(19) United States
(12) Patent Application Publication
(10) Pub. No.: US 2023/0157172 A1
(43) Pub. Date: May 18, 2023

(54) ENHANCED THERMOELECTRIC PERFORMANCE OF DOPED PEROVSKITE MATERIALS

(71) Applicants: Xiong Gong, Hudson, OH (US); Luyao Zheng, State College, PA (US)

(72) Inventors: Xiong Gong, Hudson, OH (US); Luyao Zheng, State College, PA (US)

(21) Appl. No.: 18/055,637

(22) Filed: Nov. 15, 2022

Related U.S. Application Data
(60) Provisional application No. 63/279,354, filed on Nov. 15, 2021.

(51) Int. Cl. H01L 35/30

(52) U.S. Cl. CPC H01L 35/28; H01L 35/14; H01L 35/24

(57) ABSTRACT

A thermoelectric thin film material including an organic-inorganic hybrid perovskite doped with an organic dopant represented by the general expression ABX₃ where A is an A-site cation, B is a B-site cation, and X is a halide anion. A method of making a thermoelectric thin film material including forming an organic-inorganic hybrid perovskite doped with an organic dopant represented by the general expression ABX₃ where A is an A-site cation, B is a B-site cation, and X is a halide anion. A thermoelectric device comprising a thermoelectric thin film material.

### CROSS-REFERENCE TO RELATED APPLICATIONS

This application claims priority to U.S. Provisional Patent Application No. 63/279,354 entitled “Enhanced Thermoelectronic Performance from Dopped Perovskite Materials”, filed on Nov. 15, 2021, the contents of which are incorporated herein by reference.

### FIELD OF THE INVENTION

The invention relates to thermoelectric materials for use in thermoelectric devices, specifically the thermoelectric materials include organic-inorganic hybrid perovskites with improved thermoelectric performance through chemical doping.

### BACKGROUND OF THE INVENTION

Thermoelectric materials have been studied over the past decades for converting heat into electricity. Many semiconductors have been intensively investigated in order to find materials with suitable electrical and thermal conductivities as well as improved Seebeck coefficients. Nanostructured GeTe, PbTe, PbS and SnTe alloys possess both high electrical conductivities and Seebeck coefficients, as well as high thermal conductivities. Such state-of-the-art inorganic thermoelectric materials could exhibit a ZT value over 1, their high-temperature processing restricts their practical applications. Organic semiconductors possess low thermal conductivities, poor electrical conductivities and low Seebeck coefficients, and consequently low ZT values.

Organic-inorganic hybrid perovskites have been mostly investigated for achieving cost-effective and efficient photovoltaics. Minimal attention has been applied to hybrid perovskites for their thermoelectric applications. It has been reported that organic-inorganic hybrid perovskites possess an intrinsic “electron-crystal phonon-glass” and a phonon inhibiting structure. This structure provides low thermal conductivities. However, Pb-based and Sn-based perovskites are reported to have low electrical conductivities and relatively decent electrical conductivities, respectively. Thus, there is a need for cost-effective less-toxic organic-inorganic hybrid perovskites with improved electrical conductivities to obtain thermoelectric materials with superior thermoelectric performance at room temperature.

### SUMMARY OF THE INVENTION

An embodiment of the present invention provides a thermoelectric thin film material comprising a hybrid perovskite represented by the general expression, ABX₃, where A is an A-site cation, B is a B-site cation, and X is a halide anion, and wherein the hybrid perovskite is doped with an organic dopant.

Another embodiment of the present invention provides a thermoelectric thin film material as in any embodiment above, wherein the A-site cation comprises one or more of CH₃NH₃¹⁺, NH₂CH₂═NH₂¹⁺, and Cs⁺.

Another embodiment of the present invention provides a thermoelectric thin film material as in any embodiment above, wherein the B-site cation comprises one or more of Pb²⁺ and Sn²⁺.

Another embodiment of the present invention provides a thermoelectric thin film material as in any embodiment above, wherein the one or more of Pb²⁺ and Sn²⁺ is partially substituted by one or more divalent metal cation selected from Cu²⁺, Ni²⁺, Fe²⁺, Mn²⁺, Pd²⁺, Cd²⁺, Ge²⁺, and Eu²⁺.

Another embodiment of the present invention provides a thermoelectric thin film material as in any embodiment above, wherein the one or more of Pb²⁺ and Sn²⁺ is partially substituted by one or more trivalent metal cations selected from Bi3⁺, Nd³⁺, En³⁺, and Pr³⁺.

Another embodiment of the present invention provides a thermoelectric thin film material as in any embodiment above, wherein the halide anion comprises one or more of Cl⁻, Br⁻, and I⁻.

Another embodiment of the present invention provides a thermoelectric thin film material as in any embodiment above, wherein the A-site cation is NH₂CH₂═NH₂¹⁺, wherein the B-site cation is Sn²⁺, and wherein the halide anion is I⁻.

Another embodiment of the present invention provides a thermoelectric thin film material as in any embodiment above, wherein the organic dopant is a p-type dopant.

Another embodiment of the present invention provides a thermoelectric thin film material as in any embodiment above, wherein the p-type dopant comprises at least one of TCNQ (7,7,8,8-tetracyanoquinodimethane), F4-TCNQ (2,3,5,6-tetrafluoro-7,7,8,8-tetracyanoquinodimethane), LiTFSI (Lithium bis(trifluoromethylsulphonyl)imide), FK102-Co(III)TFSi Salt (Tris(2-(1H-pyrazol-1-yl)pyridine)cobalt(III) tri[hexafluorophosphate]), Ir(mppy)3 (Tris[2-(p-tolyl)pyridine]iridium(III)), NPNPB (N,N′-diphenyl-N,N′-di-[4-(N,N-diphenyl-amino)phenyl]benzidine), BCF (Tris(pentafluorophenyl)borane), PMA (phosphomolybdic acid), TFSA (bis(trifluoromethane)sulfonimide), MPMA (12-molybdophosphoric acid hydrate), and any derivatives thereof.

Another embodiment of the present invention provides a thermoelectric thin film material as in any embodiment above, wherein the p-type dopant is F4-TCNQ (2,3,5,6-tetrafluoro-7,7,8,8-tetracyanoquinodimethane).

Another embodiment of the present invention provides a thermoelectric thin film material as in any embodiment above, wherein the organic dopant is an n-type dopant.

Another embodiment of the present invention provides a thermoelectric thin film material as in any embodiment above, wherein the n-type dopant comprises at least one of o-MeO-DMBI (2-(2-methoxyphenyl)-1,3-dimethyl-2,3-dihydro-1H-benzoimidazole), PXZ-DPS (0-(4-(4-(10H-Phenoxazin-10-yl)phenylsulfonyl)phenyl)-10H-phenoxazine), BV (benzyl viologen), DQ (diquat), N-DMBI ((4-(1,3 dimethyl-2,3-dihydro-1H-benzoimidazol-2-yl)phenyl)dimethylamine), TBAI (tetrabutylammonium iodide), TBAA (tetrabutylammonium acetate), and any derivatives thereof.

Another embodiment of the present invention provides a thermoelectric thin film material as in any embodiment above, wherein a doping level of the hybrid perovskite is greater than about 0% based upon the molar ratio of the organic dopant and the hybrid perovskite.

Another embodiment of the present invention provides a thermoelectric thin film material as in any embodiment above, wherein a measured ZT value of the thermoelectric thin film is at least two times larger than a measured ZT value of an equivalent non-doped hybrid perovskite.

An embodiment of the present invention provides a method of making a thermoelectric thin film material, the method including forming a hybrid perovskite, wherein the hybrid perovskite represented by the general expression, ABX₃, where A is the A-site cation, B is a B-site cation, and X is a halide anion, and wherein the hybrid perovskite is doped with an organic dopant.

Another embodiment of the present invention provides a method of making a thermoelectric thin film material as in any embodiment above, wherein the step of forming a hybrid perovskite is selected from one-step solution-processing and two-step solution-processing methods.

Another embodiment of the present invention provides a method of making a thermoelectric thin film material as in any embodiment above, wherein the step of forming a hybrid perovskite is a one-step solution processing method including spin coating an organic perovskite precursor, an inorganic perovskite precursor, and an organic dopant precursor, onto a substrate to thereby form a doped organic-inorganic hybrid perovskite precursor; and converting the organic perovskite precursor, the inorganic perovskite precursor, and the organic dopant precursor, into the thermoelectric thin film material.

Another embodiment of the present invention provides a method of making a thermoelectric thin film material as in any embodiment above, wherein the step of forming a hybrid perovskite is a two-step solution processing method including sequentially spin coating layers of an organic perovskite precursor, an inorganic perovskite precursor, and an organic dopant precursor, onto a substrate to thereby form a doped organic-inorganic hybrid perovskite precursor; and converting the organic perovskite precursor, the inorganic perovskite precursor, and the organic dopant precursor, into the thermoelectric thin film material.

An embodiment of the present invention provides a thermoelectric device including the thermoelectric thin film material according to any embodiment above.

### BRIEF DESCRIPTION OF THE DRAWINGS

FIG. 1 shows a graph of electrical conductivity related to doping level as measured according to embodiments of the present invention.

FIG. 2 shows a graph of charge carrier concentration related to doping level as measured according to embodiments of the present invention.

FIGS. 3A-3E are scanning electron microscope (SEM) images of thin films according to embodiments of the present invention.

FIG. 4 shows a graph of thermal conductivity related to doping level as measured according to embodiments of the present invention.

FIG. 5 shows a graph of Seebeck coefficient related to doping level as measured according to embodiments of the present invention.

FIG. 6 shows a graph of ZT related to doping level as measured according to embodiments of the present invention.

### DETAILED DESCRIPTION OF ILLUSTRATIVE EMBODIMENTS

For thermoelectric applications, the conversion of heat into electricity, increased charge carrier concentrations and mobilities are highly desirable in significantly improving electrical conductivities and thus thermoelectric performance. It is further desirable to provide superior thin film morphologies for the significant improvement of electrical conductivities. It has been discovered that the thermoelectric performance of thermoelectric materials, including organic-inorganic hybrid perovskites, is increased when chemical dopants are incorporated into the perovskite structure.

Thermoelectric performance is evaluated using a dimensionless figure of merit, ZT, which is described as:

$$ZT = \frac{{σ S}^{2}}{k} T$$

where σ is the electrical conductivity, S is the Seebeck coefficient, k is the thermal conductivity, and T, is the absolute temperature. Increased ZT values indicate higher thermoelectric performance. Thus, embodiments of the present invention possess increased electrical conductivities, Seebeck coefficients, and reduced thermal conductivities to increase thermoelectric performance.

The power factor, PF, is another parameter used to evaluate the thermoelectric performance. The power factor, PF, is described as:

PF=σS²

Where σ is the electrical conductivity and S is the Seebeck coefficient.

The electrical conductivity, a, is described as:

σ=qnμ

where q is the elementary charge, n is the charge carrier concentration and p is the charge carrier mobility, respectively. Thus, there is a direct relationship between the electrical conductivities and the doping levels (charge carrier concentrations as measured using capacitance-voltage measurements according to the Mott-Schottky model).

The thermal conductivity, k, may be experimentally observed and is described as:

$$k = \frac{( I - B ) ( \frac{1}{4 a} + \frac{H γ}{π Fm} + \frac{1}{{π r}_{0}} )}{A}$$

where I is the probe current, H is the micro-hardness, is y the effective roughness, F is the contact force, m is the effective slope between the tip and the sample, a is the tip radius, r₀ is the radius of the heat source, and A and B are the model constants, respectively.

The Seebeck coefficient, S, may be experimentally observed and is described by:

$$S = \frac{8 {π}^{2} {k}_{B}^{2}}{3 {qh}^{2}} {m}^{*} {T ( \frac{π}{3 n} )}^{2 / 3}$$

where k_{B} is the Boltzmann constant, q is the elementary charge, h is the Planck constant, m* is the effective mass, T is the temperature, and n is the charge carrier density.

As demonstrated by the above relationships, improved thermoelectric performance, as measured using ZT or power factor, PF, is achieved by increasing electrical conductivity, increasing the Seebeck coefficient, and decreasing thermal conductivity.

In a first aspect, the present invention is directed to an organic-inorganic perovskite capable of being chemically doped. Typically, organic-inorganic perovskites are represented by the formula ABX₃, where A is an organic cation, B is a metal cation, and X is a halide anion, wherein the ABX₃ notation is representative of the three-dimensional crystalline structure of the perovskite. The cations, A and B, are of different sizes.

Organic-inorganic perovskites are hybrid materials exhibiting combined properties of organic composites and inorganic crystalline materials. The inorganic component forms a framework bound by covalent and ionic interactions, which provide high carrier mobility. The organic component helps in the self-assembly process of those materials, it also enables the hybrid materials to be deposited by low-cost technique as other organic materials. An additional property of the organic component is to tailor the electronic properties of the organic-inorganic material by adjusting its dimensionality and the electronic coupling between the inorganic sheets.

Without wishing to be limited by theory in any way, it is believed organic-inorganic perovskites possess an intrinsic “electron-crystal phonon-glass” and a phonon inhibiting structure providing superior optoelectronic properties and low thermal conductivities.

In some embodiments the A-site cation is CH₃NH₃¹⁺ (also known as MA¹⁺ or MA). In other embodiments the A-site cation is NH₂CH₂═NH₂¹⁺ (also known as FA¹⁺ or FA). In other embodiments the A-site cation is Cs⁺. In some embodiments the A-site cation is a combination of two or more of the above A-site cations.

In embodiments of the present invention including two or more A-site cations, the organic-inorganic perovskite may be represented as:

(Aₓ₁Aₓ₂ . . . Aₓₙ)BX₃

where x1 through xn represent the molar percentage of the A-site cation present as a decimal greater than 0 and 1 or less, such that the sum of x1 through xn is 1.000.

Either organic or inorganic A-site cations are indispensable elements in the formation of 3D frameworks of hybrid perovskite materials. The A-site cation determines the perovskite phase structure, the perovskite phase stability, and the optoelectronic properties of 3D perovskite materials. Moreover, the A-site cation plays a major role in achieving desirable lattice; otherwise, the unmatched A-site cation will distort the whole lattice.

In some embodiments the B-site cation is Pb²⁺. In other embodiments the B-site cation is Sn²⁺. In other embodiments the B-site cation is a combination of both Pb²⁺ and Sn²⁺. In embodiments containing one or both of Pb²⁺ and Sn²⁺, the Pb²⁺ and Sn²⁺ cations may be partially substituted by divalent metal cations including one or more of Cu²⁺, Ni²⁺, Fe²⁺, Mn²⁺, Pd²⁺, Cd²⁺, Ge²⁺, and Eu²⁺. In embodiments containing one or both of Pb²⁺ and Sn²⁺, the Pb²⁺ and Sn²⁺ cations may be partially substituted by trivalent metal cations including one or more of Bi3⁺, Nd³⁺, En³⁺, and Pr³⁺.

In embodiments of the present invention including two or more B-site cations, the organic-inorganic perovskite may be represented as:

A(B_{y1}B_{y2} . . . B_{yn})X₃

where y1 through yn represent the molar percentage of the B-site cation present as a decimal greater than 0 and 1 or less, such that the sum of y1 through yn is 1.000.

In some embodiments the X-site anion is a halide anion Cl⁻, Br⁻, I⁻, or a combination thereof.

In embodiments of the present invention including two or more halide anions, the organic-inorganic perovskite may be represented as:

AB(X_{z1}X_{z2} . . . Xₓₙ)₃

where z1 through zn represent the molar percentage of a present halide ion, as a decimal greater than 0 and 1 or less, such that the sum of z1 through zn is 1.000.

In embodiments including two or more of A-site cations, B-site cations, and halide anions, the perovskite may be represented as:

(Aₓ₁Aₓ₂ . . . Aₓₙ)(B_{y1}B_{y2} . . . B_{yn})(X_{z1}X_{z2} . . . Xₓₙ)₃

where x1 through xn represent the molar percentage of the A-site cation present as a decimal greater than 0 and 1 or less, such that the sum of x1 through xn is 1.000, where y1 through yn represent the molar percentage of the B-site cation present as a decimal greater than 0 and 1 or less, such that the sum of y1 through yn is 1.000, and where z1 through zn represent the molar percentage of a present halide ion, as a decimal greater than 0 and 1 or less, such that the sum of z1 through zn is 1.000.

Without wishing to be limited by theory in any way, it is believed that selection of the one or more A-site cations, one or more B-site cations, and X-site anions influences the properties of the obtained organic-inorganic hybrid perovskite structures. For example, it is understood that the FA cation has a slightly larger ionic radius than that of the MA cation, which could lead to the increase in the tolerance factor t of FA-based perovskites. The substitution of the A-site cation could induce the modification of the M-X bond angle and the bond length, which would alter the band gaps and crystal structures of 3D perovskite materials. A larger FA cation could form more symmetric crystal structure. For example, as the ionic radius of A-site cation is gradually increased, the band gaps of perovskites are gradually decreased. In addition, FA-based perovskites have smaller band gaps and possess superior thermal stability. It is additionally understood that the organic components (MA or FA cations) in perovskite materials are highly hygroscopic, volatile, and can thermally decompose at ˜200° C. Moreover, organic-inorganic hybrid perovskites are susceptible to moisture, light, and oxygen. Additionally, it is understood that mixed-organic-cation perovskites may be fabricated in order to tune the specific properties of the obtained organic-inorganic hybrid perovskite.

For the B-site cation, it is understood that the lead cation (Pb²⁺) and tin cation (Sn²⁺) have similar ionic radii and are useful in organic-inorganic hybrid perovskites. Due to the toxicity of lead, there is strong motivation to substitute lead cations with less toxic or non-toxic alternatives. It is further understood that the properties of the obtained organic-inorganic hybrid perovskite are tunable through the substitution of lead cations.

For the X anion, it is understood that halide anions affect the band gap of the obtained organic-inorganic hybrid perovskites.

Without wishing to be limited by theory in any way, it is believed that the introduction of chemical dopants into the thin film organic-inorganic hybrid perovskite improves the electrical conductivity of the thin film relative to the pure form of the thin film organic-inorganic hybrid perovskite. It is further believed that the presence of the dopants increases charge carrier concentrations and provides for improved film morphologies. It is further believed that above a certain level the presence of excess dopant has deleterious effects on film morphologies, and thus decreases electrical conductivities.

In an additional aspect, the present invention is directed to a doped organic-inorganic hybrid perovskite, as described below. In some embodiments, the organic-inorganic hybrid perovskite is doped with one or more dopants. For example, the organic-inorganic hybrid perovskite structures described above may be doped with an organic dopant. Suitable organic dopants may include p-type dopants and n-type dopants. In some embodiments, the organic dopant is a fluorinated dopant.

The p-type dopant is not particularly limited and one of ordinary skill in the art will be able to select a suitable p-type dopant without undue experimentation. In various embodiments a suitable p-type dopant may include, without limitation, one or more of TCNQ (7,7,8,8-tetracyanoquinodimethane), F4-TCNQ (2,3,5,6-tetrafluoro-7,7,8,8-tetracyanoquinodimethane), LiTFSI (Lithium bis(trifluoromethylsulphonyl)imide), FK102-Co(III)TFSi Salt (Tris(2-(1H-pyrazol-1-yl)pyridine)cobalt(III) tri[hexafluorophosphate]), Ir(mppy)₃ (Tris[2-(p-tolyl)pyridine]iridium(III)), NPNPB (N,N′-diphenyl-N,N′-di-[4-(N,N-diphenyl-amino)phenyl]benzidine), BCF (Tris(pentafluorophenyl)borane), PMA (phosphomolybdic acid), TFSA (bis(trifluoromethane)sulfonimide), MPMA (12-molybdophosphoric acid hydrate), and any derivatives thereof.

The n-type dopant is not particularly limited and one of ordinary skill in the art will be able to select a suitable n-type dopant without undue experimentation. In various embodiments a suitable n-type dopant may include, without limitation, one or more of o-MeO-DMBI (2-(2-methoxyphenyl)-1,3-dimethyl-2,3-dihydro-1H-benzoimidazole), PXZ-DPS (0-(4-(4-(10H-Phenoxazin-10-yl)phenylsulfonyl)phenyl)-10H-phenoxazine), BV (benzyl viologen), DQ (diquat), N-DMBI ((4-(1,3 dimethyl-2,3-dihydro-1H-benzoimidazol-2-yl)phenyl)dimethylamine), TBAI (tetrabutylammonium iodide), TBAA (tetrabutylammonium acetate), and any derivatives thereof.

In some embodiments, thermoelectric thin film materials according to the present invention comprise organic-inorganic hybrid perovskites doped with an effective amount of one or more dopants. In these and other embodiments, an effective amount of dopant is understood to increase the electrical conductivity, increase the charge carrier concentration and thus the Seebeck coefficient, and improve the morphologies of thermoelectric thin films relative to the pristine organic-inorganic hybrid perovskite. It is further understood that in these and other embodiments, an effective amount of dopant is below an excess amount of dopant where excess dopant is understood to have deleterious effects on the morphologies of the thermoelectric thin film materials. Deleterious effects include cracks in the thin film structure. In some embodiments, an effective amount of dopant provides for improved grain size. Without wishing to be limited by theory in any way, it is believed that enlarged grain sizes facilitate charge carrier transport, thus increasing charge carrier mobilities.

In some embodiments thermoelectric thin films comprising doped organic-inorganic perovskites have a doping level of greater than 0.00%. In other embodiments, about 0.05% or greater. In other embodiments, about 0.10% or greater. In other embodiments, about 0.15% or greater. In other embodiments, about 0.20% or greater. In other embodiments, about 0.25% or greater. In other embodiments, about 0.30% or greater. In other embodiments, about 0.35% or greater. In other embodiments, about 0.40% or greater. In other embodiments, about 0.45% or greater. In other embodiments, about 0.50% or greater. In other embodiments, about 0.55% or greater. In other embodiments, about 0.60% or greater. In other embodiments, about 0.65% or greater. In other embodiments, about 0.70% or greater. In other embodiments, about 0.75% or greater. In other embodiments, about 0.80% or greater. In other embodiments, about 0.85% or greater. In other embodiments, about 0.90% or greater. In other embodiments, about 0.95% or greater. In other embodiments, about 1.00% or greater. In other embodiments, about 2.00% or greater. In other embodiments, about 3.00% or greater. In other embodiments, about 4.00% or greater. In other embodiments, about 5.00% or greater. In other embodiments, about 6.00% or greater. In other embodiments, about 7.00% or greater. In other embodiments, about 8.00% or greater. In other embodiments, about 9.00% or greater. In other embodiments, about 10.00% or greater. In other embodiments, about 11.00% or greater. In other embodiments, about 12.00% or greater. In other embodiments, about 13.00% or greater. In other embodiments, about 14.00% or greater. In other embodiments, about 15.00% or greater. In other embodiments, about 16.00% or greater. In other embodiments, about 17.00% or greater. In other embodiments, about 18.00% or greater. In other embodiments, about 19.00% or greater. In other embodiments, about 20.00% or greater. In other embodiments, about 21.00% or greater. In other embodiments, about 22.00% or greater. In other embodiments, about 23.00% or greater. In other embodiments, about 24.00% or greater. In other embodiments, about 25.00% or greater. In other embodiments, about 30.00% or greater. In other embodiments, about 40.00% or greater. In other embodiments, about 50.00% or greater. In other embodiments, about 60.00% or greater. In other embodiments, about 70.00% or greater. In other embodiments, about 80.00% or greater. In other embodiments, about 90.00% or greater.

In some embodiments thermoelectric thin films comprising doped organic-inorganic perovskites have a doping level of about less than 100.00%. In other embodiments, about 90.00% or less. In other embodiments, about 80.00% or less. In other embodiments, about 70.00% or less. In other embodiments, about 60.00% or less. In other embodiments, about 50.00% or less. In other embodiments, about 40.00% or less. In other embodiments, about 30.00% or less. In other embodiments, about 25.00% or less. In other embodiments, about 24.00% or less. In other embodiments, about 23.00% or less. In other embodiments, about 22.00% or less. In other embodiments, about 21.00% or less. In other embodiments, about 20.00% or less. In other embodiments, about 19.00% or less. In other embodiments, about 18.00% or less. In other embodiments, about 17.00% or less. In other embodiments, about 16.00% or less. In other embodiments, about 15.00% or less. In other embodiments, about 14.00% or less. In other embodiments, about 13.00% or less. In other embodiments, about 12.00% or less. In other embodiments, about 11.00% or less. In other embodiments, about 10.00% or less. In other embodiments, about 9.00% or less. In other embodiments, about 8.00% or less. In other embodiments, about 7.00% or less. In other embodiments, about 6.00% or less. In other embodiments, about 5.00% or less. In other embodiments, about 4.00% or less. In other embodiments, about 3.00% or less. In other embodiments, about 2.00% or less. In other embodiments, about 1.00% or less.

In some embodiments thermoelectric thin films comprising doped organic-inorganic perovskites have a doping level of from about greater than 0.00% to about less than 100%. In other embodiments, about greater than 0.00% to about 90.00%. In other embodiments, about greater than 0.00% to about 80.00%. In other embodiments, about greater than 0.00% to about 70.00%. In other embodiments, about greater than 0.00% to about 60.00%. In other embodiments, about greater than 0.00% to about 50.00%. In other embodiments, about greater than 0.00% to about 40.00%. In other embodiments, about greater than 0.00% to about 30.00%. In other embodiments, about greater than 0.00% to about 25.00%. In other embodiments, about greater than 0.00% to about 24.00%. In other embodiments, about greater than 0.00% to about 23.00%. In other embodiments, about greater than 0.00% to about 22.00%. In other embodiments, about greater than 0.00% to about 21.00%. In other embodiments, about greater than 0.00% to about 20.00%. In other embodiments, about greater than 0.00% to about 19.00%. In other embodiments, about greater than 0.00% to about 18.00%. In other embodiments, about greater than 0.00% to about 17.00%. In other embodiments, about greater than 0.00% to about 16.00%. In other embodiments, about greater than 0.00% to about 15.00%. In other embodiments, about greater than 0.00% to about 14.00%. In other embodiments, about greater than 0.00% to about 13.00%. In other embodiments, about greater than 0.00% to about 12.00%. In other embodiments, about greater than 0.00% to about 11.00%. In other embodiments, about greater than 0.00% to about 10.00%. In other embodiments, about greater than 0.00% to about 9.00%. In other embodiments, about greater than 0.00% to about 8.00%. In other embodiments, about greater than 0.00% to about 7.00%. In other embodiments, about greater than 0.00% to about 6.00%. In other embodiments, about greater than 0.00% to about 5.00%. In other embodiments, about greater than 0.00% to about 4.00%. In other embodiments, about greater than 0.00% to about 3.00%. In other embodiments, about greater than 0.00% to about 2.00%. In other embodiments, about greater than 0.00% to about 1.00%. In other embodiments, about greater than 0.00% to about 15.00%. In other embodiments, about 1.00% to about 15.00%. In other embodiments, about 2.00% to about 15.00%. In other embodiments, about 3.00% to about 15.00%. In other embodiments, about 4.00% to about 15.00%. In other embodiments, about 5.00% to about 15.00%. In other embodiments, about 6.00% to about 15.00%. In other embodiments, about 7.00% to about 15.00%. In other embodiments, about 8.00% to about 15.00%. In other embodiments, about 9.00% to about 15.00%. In other embodiments, about 10.00% to about 15.00%. In other embodiments, about 11.00% to about 15.00%. In other embodiments, about 12.00% to about 15.00%. In other embodiments, about 13.00% to about 15.00%. In other embodiments, about 14.00% to about 15.00%.

In some embodiments thermoelectric thin films have a thickness of about 50 nm or greater. In other embodiments, about 100 nm or greater. In other embodiments, about 150 nm or greater. In other embodiments, about 200 nm or greater. In other embodiments, about 250 nm or greater. In other embodiments, about 300 nm or greater. In other embodiments, about 350 nm or greater. In other embodiments, about 400 nm or greater. In other embodiments, about 450 nm or greater. In other embodiments, about 500 nm or greater. In other embodiments, about 550 nm or greater. In other embodiments, about 600 nm or greater. In other embodiments, about 650 nm or greater. In other embodiments, about 700 nm or greater. In other embodiments, about 750 nm or greater. In other embodiments, about 800 nm or greater. In other embodiments, about 850 nm or greater. In other embodiments, about 900 nm or greater. In other embodiments, about 950 nm or greater. In other embodiments, about 1.000 micron or greater. In other embodiments, about 1.500 microns or greater. In other embodiments, about 2.000 microns or greater. In other embodiments, about 2.500 microns or greater. In other embodiments, about 3.000 microns or greater. In other embodiments, about 3.500 microns or greater. In other embodiments, about 4.000 microns or greater. In other embodiments, about 4.500 microns or greater. In other embodiments, about 5.000 microns or greater.

In some embodiments thermoelectric thin films have a thickness of about 5.000 microns or less. In other embodiments, about 4.500 microns or less. In other embodiments, about 4.000 microns or less. In other embodiments, about 3.500 microns or less. In other embodiments, about 3.000 microns or less. In other embodiments, about 2.500 microns or less. In other embodiments, about 2.000 microns or less. In other embodiments, about 1.500 microns or less. In other embodiments, about 1.000 microns or less. In other embodiments, about 950 nm or less. In other embodiments, about 900 nm or less. In other embodiments, about 850 nm or less. In other embodiments, about 800 nm or less. In other embodiments, about 750 nm or less. In other embodiments, about 700 nm or less. In other embodiments, about 650 nm or less. In other embodiments, about 600 nm or less. In other embodiments, about 550 nm or less. In other embodiments, about 500 nm or less. In other embodiments, about 450 nm or less. In other embodiments, about 400 nm or less. In other embodiments, about 350 nm or less. In other embodiments, about 300 nm or less. In other embodiments, about 250 nm or less. In other embodiments, about 200 nm or less. In other embodiments, about 150 nm or less. In other embodiments, about 100 nm or less. In other embodiments, about 50 nm or less.

In some embodiments thermoelectric thin films have a thickness from about 50 nm to about 5.000 microns. In other embodiments, from about 50 nm to about 4.500 microns. In other embodiments, from about 50 nm to about 4.000 microns. In other embodiments, from about 50 nm to about 3.500 microns. In other embodiments, from about 50 nm to about 3.000 microns. In other embodiments, from about 50 nm to about 2.500 microns. In other embodiments, from about 50 nm to about 2.000 microns. In other embodiments, from about 50 nm to about 1.500 microns. In other embodiments, from about 50 nm to about 1.000 microns. In other embodiments, from about 50 nm to about 950 nm. In other embodiments, from about 50 nm to about 900 nm.

The following properties of embodiments according to the present invention are understood to be as measured at ambient conditions, including temperature and pressure. Ambient conditions are understood to be approximately atmospheric pressure and room temperature.

In some embodiments thermoelectric thin films have an electrical conductivity of about 1.00×10⁻³ S/cm or greater. In other embodiments, about 1.00×10⁻² S/cm or greater. In other embodiments, about 1.00×10⁻¹ S/cm or greater. In other embodiments, about 1 S/cm or greater. In other embodiments, about 10 S/cm or greater. In other embodiments, about 100 S/cm or greater. In other embodiments, about 1000 S/cm or greater.

In some embodiments thermoelectric thin films have an electrical conductivity of about 1000 S/cm or less. In other embodiments, about 100 S/cm or less. In other embodiments, about 10 S/cm or less. In other embodiments, about 1 S/cm or less. In other embodiments, about 1.00×10⁻¹ S/cm or less. In other embodiments, about 1.00×10⁻² S/cm or less. In other embodiments, about 1.00×10⁻³ S/cm or less.

In some embodiments thermoelectric thin films have an electrical conductivity of from about 1.00×10⁻³ S/cm to about 1000 S/cm. In other embodiments, about 1.00×10⁻² S/cm to about 100 S/cm. In other embodiments, about 1.00×10⁻¹ S/cm to about 100 S/cm. In other embodiments, about I² S/cm to about 100 S/cm. In other embodiments, about 1 S/cm to about 50 S/cm.

In some embodiments thermoelectric thin films comprising doped organic-inorganic hybrid perovskites have an increased electrical conductivity relative to the corresponding undoped organic-inorganic hybrid perovskite by a factor of about 2 or greater. In some embodiments, about 2.5 or greater. In some embodiments, about 3 or greater. In some embodiments, about 3.5 or greater. In some embodiments, about 4 or greater. In some embodiments, about 4.5 or greater. In some embodiments, about 5 or greater. In some embodiments, about 10 or greater. In some embodiments, about 100 or greater. In some embodiments, about 1000 or greater. In some embodiments, about 10000 or greater.

In some embodiments thermoelectric thin films comprising doped organic-inorganic hybrid perovskites have an increased electrical conductivity relative to the corresponding undoped organic-inorganic hybrid perovskite by a factor of about 10000 or less. In some embodiments, about 1000 or less. In some embodiments, about 100 or less. In some embodiments, about 10 or less. In some embodiments, about 5 or less. In some embodiments, about 4 or less. In some embodiments, about 3 or less. In some embodiments, about 2 or less.

In some embodiments thermoelectric thin films comprising doped organic-inorganic hybrid perovskites have an increased electrical conductivity relative to the corresponding undoped organic-inorganic hybrid perovskite by a factor of from about 2 to about 10000. In some embodiments, from about 2 to about 1000. In some embodiments, from about 2 to about 100. In some embodiments, from about 2 to about 10. In some embodiments, from about 2 to about 5. In some embodiments, from about 2 to about 4. In some embodiments, from about 2 to about 3.

In some embodiments thermoelectric thin films have a thermal conductivity of about 0.001 W/m·K or greater. In other embodiments, about 0.010 W/m·K or greater. In other embodiments, about 0.050 W/m·K or greater. In other embodiments, about 0.100 W/m·K or greater. In other embodiments, about 0.150 W/m·K or greater. In other embodiments, about 0.200 W/m·K or greater. In other embodiments, about 0.250 W/m·K or greater. In other embodiments, about 0.300 W/m·K or greater. In other embodiments, about 0.350 W/m·K or greater. In other embodiments, about 0.400 W/m·K or greater. In other embodiments, about 0.450 W/m·K or greater. In other embodiments, about 0.500 W/m·K or greater.

In some embodiments thermoelectric thin films have a thermal conductivity of about 0.500 W/m·K or less. In other embodiments, about 0.450 W/m·K or less. In other embodiments, about 0.400 W/m·K or less. In other embodiments, about 0.350 W/m·K or less. In other embodiments, about 0.300 W/m·K or less. In other embodiments, about 0.250 W/m·K or less. In other embodiments, about 0.200 W/m·K or less. In other embodiments, about 0.150 W/m·K or less. In other embodiments, about 0.100 W/m·K or less. In other embodiments, about 0.050 W/m·K or less. In other embodiments, about 0.010 W/m·K or less. In other embodiments, about 0.001 W/m·K or less.

In some embodiments thermoelectric thin films have a thermal conductivity of from about 0.001 W/m·K to about 0.500 W/m·K. In other embodiments, about 0.010 W/m·K to about 0.500 W/m·K. In other embodiments, about 0.050 W/m·K to about 0.500 W/m·K. In other embodiments, about 0.100 W/m·K to about 0.500 W/m·K. In other embodiments, about 0.150 W/m·K to about 0.500 W/m·K. In other embodiments, about 0.200 W/m·K to about 0.500 W/m·K. In other embodiments, about 0.250 W/m·K to about 0.500 W/m·K.

In some embodiments thermoelectric thin films have a Seebeck coefficient of about 10 μV/K or greater. In other embodiments, about 100 μV/K or greater. In other embodiments, about 125 μV/K or greater. In other embodiments, about 150 μV/K or greater. In other embodiments, about 175 μV/K or greater. In other embodiments, about 200 μV/K or greater. In other embodiments, about 225 μV/K or greater. In other embodiments, about 250 μV/K or greater. In other embodiments, about 275 μV/K or greater. In other embodiments, about 300 μV/K or greater. In other embodiments, about 325 μV/K or greater. In other embodiments, about 350 μV/K or greater. In other embodiments, about 375 μV/K or greater. In other embodiments, about 400 μV/K or greater. In other embodiments, about 425 μV/K or greater. In other embodiments, about 450 μV/K or greater. In other embodiments, about 475 μV/K or greater. In other embodiments, about 500 μV/K or greater. In other embodiments, about 1000 μV/K or greater. In other embodiments, about 2000 μV/K or greater. In other embodiments, about 3000 μV/K or greater. In other embodiments, about 4000 μV/K or greater. In other embodiments, about 5000 μV/K or greater.

In some embodiments thermoelectric thin films have a Seebeck coefficient of about 5000 μV/K or less. In other embodiments, about 4000 μV/K or less. In other embodiments, about 3000 μV/K or less. In other embodiments, about 2000 μV/K or less. In other embodiments, about 1000 μV/K or less. In other embodiments, about 500 μV/K or less. In other embodiments, about 475 μV/K or less. In other embodiments, about 450 μV/K or less. In other embodiments, about 425 μV/K or less. In other embodiments, about 400 μV/K or less. In other embodiments, about 375 μV/K or less. In other embodiments, about 350 μV/K or less. In other embodiments, about 325 μV/K or less. In other embodiments, about 300 μV/K or less. In other embodiments, about 275 μV/K or less. In other embodiments, about 250 μV/K or less. In other embodiments, about 225 μV/K or less. In other embodiments, about 200 μV/K or less. In other embodiments, about 175 μV/K or less. In other embodiments, about 150 μV/K or less. In other embodiments, about 125 μV/K or less. In other embodiments, about 100 μV/K or less. In other embodiments, about 10 μV/K or less.

In some embodiments thermoelectric thin films have a Seebeck coefficient of about 10 μV/K to about 5000 μV/K. In other embodiments, about 100 μV/K to about 5000 μV/K. In other embodiments, about 100 μV/K to about 4000 μV/K. In other embodiments, about 100 μV/K to about 3000 μV/K. In other embodiments, about 100 μV/K to about 2000 μV/K. In other embodiments, about 100 μV/K to about 1000 μV/K. In other embodiments, about 100 μV/K to about 500 μV/K. In other embodiments, about 100 μV/K to about 475 μV/K. In other embodiments, about 100 μV/K to about 450 μV/K. In other embodiments, about 100 μV/K to about 425 μV/K. In other embodiments, about 100 μV/K to about 400 μV/K. In other embodiments, about 100 μV/K to about 375 μV/K. In other embodiments, about 100 μV/K to about 350 μV/K. In other embodiments, about 100 μV/K to about 325 μV/K. In other embodiments, about 100 μV/K to about 300 μV/K.

In some embodiments thermoelectric thin films comprising doped organic-inorganic hybrid perovskites have an increased Seebeck coefficient relative to the corresponding undoped organic-inorganic hybrid perovskite by a factor of about 1.10 or greater. In some embodiments, about 1.15 or greater. In some embodiments, about 1.20 or greater. In some embodiments, about 1.25 or greater. In some embodiments, about 1.30 or greater. In some embodiments, about 1.35 or greater. In some embodiments, about 1.40 or greater. In some embodiments, about 1.45 or greater. In some embodiments, about 1.50 or greater. In some embodiments, about 1.55 or greater. In some embodiments, about 1.60 or greater. In some embodiments, about 1.65 or greater. In some embodiments, about 1.70 or greater. In some embodiments, about 1.75 or greater. In some embodiments, about 1.80 or greater. In some embodiments, about 1.85 or greater. In some embodiments, about 1.90 or greater. In some embodiments, about 1.95 or greater. In some embodiments, about 2.00 or greater. In some embodiments, about 2.50 or greater. In some embodiments, about 3.00 or greater. In some embodiments, about 3.50 or greater. In some embodiments, about 4.00 or greater. In some embodiments, about 4.50 or greater. In some embodiments, about 5.00 or greater. In some embodiments, about 10.00 or greater.

In some embodiments thermoelectric thin films comprising doped organic-inorganic hybrid perovskites have an increased Seebeck coefficient relative to the corresponding undoped organic-inorganic hybrid perovskite by a factor of about 10.00 or less. In some embodiments, about 5.00 or less. In some embodiments, about 4.50 or less. In some embodiments, about 4.00 or less. In some embodiments, about 3.50 or less. In some embodiments, about 3.00 or less. In some embodiments, about 2.50 or less. In some embodiments, about 2.00 or less. In some embodiments, about 1.95 or less. In some embodiments, about 1.90 or less. In some embodiments, about 1.85 or less. In some embodiments, about 1.80 or less. In some embodiments, about 1.75 or less. In some embodiments, about 1.70 or less. In some embodiments, about 1.65 or less. In some embodiments, about 1.60 or less. In some embodiments, about 1.55 or less. In some embodiments, about 1.50 or less. In some embodiments, about 1.45 or less. In some embodiments, about 1.40 or less. In some embodiments, about 1.35 or less. In some embodiments, about 1.30 or less. In some embodiments, about 1.25 or less. In some embodiments, about 1.20 or less. In some embodiments, about 1.15 or less. In some embodiments, about 1.10 or less.

In some embodiments thermoelectric thin films comprising doped organic-inorganic hybrid perovskites have an increased Seebeck coefficient relative to the corresponding undoped organic-inorganic hybrid perovskite by a factor of from about # to about #. In some embodiments, from about # to about #.

In some embodiments thermoelectric thin films have a power factor (PF) of about 1.00 μW/m·K² or greater. In other embodiments, about 10.00 μW/m·K² or greater. In other embodiments, about 50.00 μW/m·K² or greater. In other embodiments, about 100.00 μW/m·K² or greater. In other embodiments, about 110.00 μW/m·K² or greater. In other embodiments, about 120.00 μW/m·K² or greater. In other embodiments, about 130.00 μW/m·K² or greater. In other embodiments, about 140.00 μW/m·K² or greater. In other embodiments, about 150.00 μW/m·K² or greater. In other embodiments, about 160.00 μW/m·K² or greater. In other embodiments, about 170.00 μW/m·K² or greater. In other embodiments, about 180.00 μW/m·K² or greater. In other embodiments, about 190.00 μW/m·K² or greater. In other embodiments, about 200.00 μW/m·K² or greater. In other embodiments, about 300.00 μW/m·K² or greater. In other embodiments, about 400.00 μW/m·K² or greater. In other embodiments, about 500.00 μW/m·K² or greater. In other embodiments, about 1000 μW/m·K² or greater.

The dimensionless value of ZT, as described above, is understood to represent thermoelectric performance. Without wishing to be limited by theory in any way, it is believed that the thermal conductivity, and thus ZT value, are different empirically and theoretically due to the micro-thermal and macro-thermal resistances due to film thicknesses. Thus, thermoelectric thin films according to the present invention possess different theoretical and empirical ZT values.

In some embodiments thermoelectric thin films have an empirical ZT value of about 0.01 or greater. In some embodiments, about 0.02 or greater. In some embodiments, about 0.03 or greater. In some embodiments, about 0.04 or greater. In some embodiments, about 0.05 or greater. In some embodiments, about 0.06 or greater. In some embodiments, about 0.07 or greater. In some embodiments, about 0.08 or greater. In some embodiments, about 0.09 or greater. In some embodiments, about 0.10 or greater. In some embodiments, about 0.11 or greater. In some embodiments, about 0.12 or greater. In some embodiments, about 0.13 or greater. In some embodiments, about 0.14 or greater. In some embodiments, about 0.15 or greater. In some embodiments, about 0.16 or greater. In some embodiments, about 0.17 or greater. In some embodiments, about 0.18 or greater. In some embodiments, about 0.19 or greater. In some embodiments, about 0.20 or greater. In some embodiments, about 0.21 or greater. In some embodiments, about 0.22 or greater. In some embodiments, about 0.23 or greater. In some embodiments, about 0.24 or greater. In some embodiments, about 0.25 or greater. In some embodiments, about 0.26 or greater. In some embodiments, about 0.27 or greater. In some embodiments, about 0.28 or greater. In some embodiments, about 0.29 or greater. In some embodiments, about 0.30 or greater. In some embodiments, about 0.31 or greater. In some embodiments, about 0.32 or greater. In some embodiments, about 0.33 or greater. In some embodiments, about 0.34 or greater. In some embodiments, about 0.35 or greater. In some embodiments, about 0.36 or greater. In some embodiments, about 0.37 or greater. In some embodiments, about 0.38 or greater. In some embodiments, about 0.39 or greater. In some embodiments, about 0.40 or greater. In some embodiments, about 0.41 or greater. In some embodiments, about 0.42 or greater. In some embodiments, about 0.43 or greater. In some embodiments, about 0.44 or greater. In some embodiments, about 0.45 or greater. In some embodiments, about 0.46 or greater. In some embodiments, about 0.47 or greater. In some embodiments, about 0.48 or greater. In some embodiments, about 0.49 or greater. In some embodiments, about 0.50 or greater. In some embodiments, about 0.60 or greater. In some embodiments, about 0.70 or greater. In some embodiments, about 0.80 or greater. In some embodiments, about 0.90 or greater. In some embodiments, about 1.00 or greater.

In some embodiments thermoelectric thin films have a theoretical ZT value of about 0.01 or greater. In some embodiments, about 0.02 or greater. In some embodiments, about 0.03 or greater. In some embodiments, about 0.04 or greater. In some embodiments, about 0.05 or greater. In some embodiments, about 0.06 or greater. In some embodiments, about 0.07 or greater. In some embodiments, about 0.08 or greater. In some embodiments, about 0.09 or greater. In some embodiments, about 0.10 or greater. In some embodiments, about 0.11 or greater. In some embodiments, about 0.12 or greater. In some embodiments, about 0.13 or greater. In some embodiments, about 0.14 or greater. In some embodiments, about 0.15 or greater. In some embodiments, about 0.16 or greater. In some embodiments, about 0.17 or greater. In some embodiments, about 0.18 or greater. In some embodiments, about 0.19 or greater. In some embodiments, about 0.20 or greater. In some embodiments, about 0.21 or greater. In some embodiments, about 0.22 or greater. In some embodiments, about 0.23 or greater. In some embodiments, about 0.24 or greater. In some embodiments, about 0.25 or greater. In some embodiments, about 0.26 or greater. In some embodiments, about 0.27 or greater. In some embodiments, about 0.28 or greater. In some embodiments, about 0.29 or greater. In some embodiments, about 0.30 or greater. In some embodiments, about 0.31 or greater. In some embodiments, about 0.32 or greater. In some embodiments, about 0.33 or greater. In some embodiments, about 0.34 or greater. In some embodiments, about 0.35 or greater. In some embodiments, about 0.36 or greater. In some embodiments, about 0.37 or greater. In some embodiments, about 0.38 or greater. In some embodiments, about 0.39 or greater. In some embodiments, about 0.40 or greater. In some embodiments, about 0.41 or greater. In some embodiments, about 0.42 or greater. In some embodiments, about 0.43 or greater. In some embodiments, about 0.44 or greater. In some embodiments, about 0.45 or greater. In some embodiments, about 0.46 or greater. In some embodiments, about 0.47 or greater. In some embodiments, about 0.48 or greater. In some embodiments, about 0.49 or greater. In some embodiments, about 0.50 or greater. In some embodiments, about 0.60 or greater. In some embodiments, about 0.70 or greater. In some embodiments, about 0.80 or greater. In some embodiments, about 0.90 or greater. In some embodiments, about 1.00 or greater. In some embodiments, about 1.10 or greater. In some embodiments, about 1.20 or greater. In some embodiments, about 1.30 or greater. In some embodiments, about 1.40 or greater. In some embodiments, about 1.50 or greater. In some embodiments, about 1.60 or greater. In some embodiments, about 1.70 or greater. In some embodiments, about 1.80 or greater. In some embodiments, about 1.90 or greater. In some embodiments, about 2.00 or greater. In some embodiments, about 2.10 or greater. In some embodiments, about 2.20 or greater. In some embodiments, about 2.30 or greater. In some embodiments, about 2.40 or greater. In some embodiments, about 2.50 or greater. In some embodiments, about 2.60 or greater.

In an additional aspect, the present invention is directed towards methods of making thermoelectric thin film materials, as described below.

In some embodiments, a method for making an organic-inorganic hybrid perovskite film with a dopant involves depositing, e.g., spin coating and other wet/solution processing methods known in the art, respective organic precursor solution, inorganic precursor solution and dopant precursor solutions onto a substrate to form a doped organic-inorganic hybrid perovskite film precursor and subsequently converting the precursors into the doped organic-inorganic hybrid perovskite. In one embodiment, such exposure can desirably be conducted at or near room temperature. Further, such exposure can desirably result in or produce well-oriented, highly-crystalline perovskite films without thermal annealing processing. The thin film may be optionally treated to remove any solvents present after forming the organic-inorganic hybrid perovskite.

In some embodiments, a method for making an organic-inorganic hybrid perovskite film with a dopant involves sequentially depositing, e.g., spin coating and other wet/solution processing methods known in the art, respective layers of organic precursor solution, inorganic precursor solution and dopant precursor solutions onto a substrate to form a hybrid perovskite film precursor with dopant precursor and subsequently converting the precursors to the doped organic-inorganic hybrid perovskite. In one embodiment, such exposure can desirably be conducted at or near room temperature. Further, such exposure can desirably result in or produce well-oriented, highly-crystalline perovskite films without thermal annealing processing. The thin film may be optionally treated to remove any solvents present after forming the organic-inorganic hybrid perovskite.

In some embodiments, the perovskite structure is synthesized at least from one or more metal and/or transition metal precursors (e.g., a lead precursor, such as a lead halide) and one or more dopant precursors (e.g., a manganese precursor, such as a manganese halide). In certain cases, a dopant precursor comprises: a manganese precursor, such as a manganese halide; a ytterbium precursor, such as a ytterbium halide; a nickel precursor, such as a nickel halide; or a combination thereof. In some embodiments, the final manganese: lead mole ratio in the synthesized perovskite structure is the same as an initial manganese: lead mole ratio in a precursor substance (e.g., a precursor solution, a precursor suspension, a precursor mixture, etc.). However, in other embodiments, the final ratio can be different than the initial ratio. Non limiting examples of lead halides include PbBr₂ and PbCl₂. Non-limiting examples of manganese halides include MnCl₂ and MnBr₂. In addition, other salts or other compounds, other than halides, may also be used, e.g., oxides.

In an additional aspect, the present invention is directed towards using thermoelectric thin film materials in thermoelectric devices. Thermoelectric thin film materials according to the present invention are suited for use in thermoelectric devices for the conversion of thermal energy into electrical energy.

A thermoelectric device creates voltage when there is a different temperature on each side. The thermoelectric effect is the direct conversion of temperature differences to electric power and vice-versa. When temperature differences are converted directly into electricity, this is called the Seebeck Effect.

In light of the foregoing, it should be appreciated that the present invention significantly advances the art by providing a thermoelectric thin film material that is structurally and functionally improved in a number of ways. While particular embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

### EXAMPLES

The following examples are offered to more fully illustrate the invention, but are not to be construed as limiting the scope thereof. Further, while some of the examples may include conclusions about the way the invention may function, the inventors do not intend to be bound by those conclusions but put them forth only as possible explanations. Moreover, unless noted by the use of the past tense, presentation of an example does not imply that an experiment or procedure was, or was not conducted, or that results were, or were not actually obtained. Efforts have been made to ensure accuracy with respect to numbers used (e.g., amounts, temperature), but some experimental errors and deviations may be present.

Materials for use in the following examples include tin(II) iodide (SnI₂, ultra-dry, 99.999%, metals basis) and molybdenum(VI) oxide (MoO₃, 99.95%, metals basis) purchased from Alfa Aesar. Formamidinium iodide (FAI) was purchased from GreatCell Solar. F4-TCNQ (97%), fullerene (C60, 99.5%), anhydrous N,N-dimethylformamide (DMF), dimethyl sulfoxide (DMSO), and toluene (99.8%) were purchased from Sigma-Aldrich. Poly(3,4-ethylenedioxythiophene):polystyrene sulfonate (PEDOT:PSS, Clevios PH1000) was purchased from Heraeus Precious Metals North America. All chemicals were used as received without further purification.

The F4-TCNQ FASnI₃ thin films were prepared through deposition of the precursor solution. For the precursor solutions, both 1M FAI and SnI₂ were dissolved in a DMF: DMSO (4:1 in volume) mixed solvent, with different concentrations of F4-TCNQ (0.01, 0.05, 0.075, and 0.1 mg mL⁻¹) by a spin-coating method. The spin coating was divided into two parts: first, the precursor solution was dripped onto substrates and the substrates were allowed to spin at 5000 rpm with an acceleration of 1000 r s⁻² for 20 seconds (s); and second, 250 mL toluene was dripped onto the wet thin films and then spin coating was carried out for another 20 s at 5000 rpm to remove the solvents. No further thermal annealing treatment was applied.

The obtained thin films were characterized according to the following methods. X-ray spectroscopy (XPS) measurement was performed. Both the pristine FASnI₃ thin film and the F4-TCNQ doped FASnI₃ thin films were deposited on glass substrates. The top 50 nm thick layer was etched off to reveal the elemental information of the bulk material rather than the surface. XPS was conducted on a PHI 5000 Versa Probe II scanning XPS microprobe. The X-ray diffraction (XRD) was performed by using a Rigaku SmartLab X-Ray Diffractometer. The electrical conductivities of both the pristine FASnI₃ thin film and the F4-TCNQ doped FASnI₃ thin films were measured by using a four-probe set up based on the van der Pauw method. Two Keithley 2400 instruments were utilized to measure the current-voltage (I-V) curves and calculate the average resistance through 8 values among the four probes. The thickness of the pristine FASnI₃ thin film and the F4-TCNQ doped FASnI₃ thin films was measured by using a DektakXT surface profile measuring system. The dielectric constants of the perovskite thin films were measured from the capacitance-frequency characteristics using a Keithley model 82-WIN Simultaneous CF System. The capacitance-voltage (C-V) measurements were carried out on a HP 4194A impedance/gain-phase analyzer under dark conditions, with an oscillating voltage of 10 mV at 10 kHz. The hole-only diode, ITO/PEDOT:PSS/FASnI₃ (or F4-TCNQ doped FASnI₃)/MoO₃/Ag diode, where ITO is indium doped tin oxide and Ag is silver, was utilized for the C-V measurement to calculate the charge carrier concentrations. The above hole-only diode was also used to estimate the hole mobility. The electron-only diode, ITO/C60/FASnI₃ (F4-TCNQ doped FASnI₃)/C60/Al, where Al is aluminum, was used to estimate the electron mobility. The charge carrier mobilities were estimated from the current densities versus voltage (J-V) characteristics obtained in the dark, based on the space charge limited current (SCLC) method. Top view scanning electron microscopy (SEM) images were obtained by using a field emission scanning electron microscope (JEOL-7401). Thermal conductivities were characterized using the scanning thermal microscopy (SThM) model, which was obtained by using a Park System XE7 atomic force microscope (AFM). The pristine FASnI₃ thin film and the F4-TCNQ doped FASnI₃ thin films were deposited on glass substrates. The thermal tip was thermally grown on a SiO₂ cantilever which was made of a silicon base. The base dimensions were 2×3 mm² and the cantilever dimensions were 150×60×1 μm³. The resistor metal was made of 5 nm NiCr and 40 nm Pd. The tip height was 12 μm and tip radius was ˜100 nm. The resistance of the tip was around 200-600Ω. The thermal coefficient of resistivity was about 1Ω ° C.⁻¹. The spring constant was 0.45 N m1 and resonance frequency was 48 kHz. The pre-setting probe current was 1.20 mA. The microhardness was characterized by the force-displacement (F-D) method with AFM. The thermal probe was used to collect the F-D data and ensured that the captured current signal and measured micro-hardness were from exactly the same region. The microhardness results were further analyzed using the Olive and Pharr model. Surface roughness was analyzed from surface topography. The slope value was determined by the calculation of the line profile via AFM original images without a flattening process. AFM was conducted by using an Atomic Park System XE7 AFM. The Seebeck coefficients were measured by using two Peltier devices, which were connected with two LFI3000 wavelength temperature controllers to generate a temperature gradient (DT) of 10 K. The characterization of thermoelectric parameters and the C-V and SCLC measurements were conducted in a glovebox with a N₂ atmosphere at room temperature.

The electrical conductivity of the pristine FASnI₃ thin film was 1.72×10⁻² S cm⁻¹, which is attributed to its low charge carrier concentrations. In order to achieve high thermoelectric performance, the electrical conductivity of the FASnI₃ thin film needs to be boosted through the use of a dopant such as F4-TCNQ. The preparation of the F4-TCNQ doped FASnI₃ thin films is described above.

XPS was first carried out to verify doping of the FASnI₃ with F4-TCNQ. High resolution XPS spectra of the pristine FASnI₃ thin film and the F4-TCNQ doped FASnI₃ thin films were compared. The appearance of F 1s orbital features for the F4-TCNQ doped FASnI₃ thin films indicated the presence of F4-TCNQ within FASnI₃ thin films. Both “═NH”, and “—NH₂” functional groups are observed for FASnI₃ thin films. The binding energies (BEs) of 398.0 eV and 397.5 eV, for “═NH” and “—NH₂” functional groups, respectively, were observed for the pristine FASnI₃ thin film. The corresponding BEs are 398.8 eV and 396.7 eV, respectively, for the F4-TCNQ doped FASnI₃ thin films. The BE shifts indicate that hydrogen bonds of ‘═NH/F’ and ‘-NH₂/F’ are formed in the F4-TCNQ doped FASnI₃ thin films. Moreover, the BEs of 495.1 eV and 486.8 eV, corresponding to the Sn 3d3/2 and Sn 3d5/2 spin-orbitals, respectively, were observed for the pristine FASnI₃ thin film. The corresponding BEs of 495.9 eV and 487.5 eV were observed for the F4-TCNQ doped FASnI₃ thin films. Furthermore, the BEs of 628.6 eV and 617.1 eV, corresponding to the I 3d3/2 and I 3d5/2 spin-orbitals, respectively, were observed for the pristine FASnI₃ thin film. The corresponding BEs of 629.1 eV and 617.6 eV, respectively, were observed for the F4-TCNQ doped FASnI₃ thin films. Such large BE shifts demonstrate that both oxidation states and chemical environments of Sn and I are dramatically different in the F4-TCNQ doped FASnI₃ thin films compared to the pristine FASnI₃ thin films. All these results demonstrate that F4-TCNQ is doped into FASnI₃ thin films.

The XRD patterns of pristine FASnI₃ and the F4-TCNQ doped thin films were obtained. It was found that both pristine FASnI₃ and F4-TCNQ doped FASnI₃ thin films possess the cubic Pnm̅3m space group at room temperature. The full width at half maximum (FWHM) of the (111) peak for the F4-TCNQ doped FASnI₃ thin film is 1.21°, which is smaller than that (1.96°) for the pristine FASnI₃ thin film, indicating that the F4-TCNQ doped FASnI₃ thin film possesses an optimal crystalline feature.

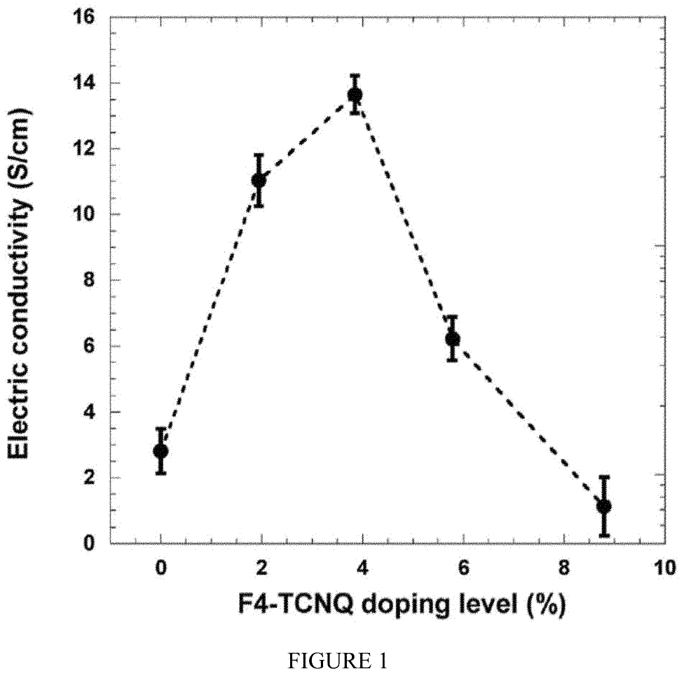

The atomic weight concentrations of elements F and Sn are calculated based on the full XPS spectra. Thus, the doping levels (a molar ratio of F4-TCNQ to FASnI₃) in the F4-TCNQ doped FASnI₃ thin films are further calculated. For example, as the doping concentration of F4-TCNQ is at 0.01 mg mL⁻¹, the doping level of F4-TCNQ within the F4-TCNQ doped FASnI₃ thin film is 1.94%. Correspondingly, the doping levels are 3.85%, 5.78% and 8.79% for F4-TCNQ concentrations of 0.05 mg mL⁻¹, 0.075 mg mL⁻¹ and 0.10 mg mL⁻¹, respectively. The electrical conductivities of the F4-TCNQ doped FASnI₃ thin films versus the doping levels of F4-TCNQ are shown in FIG. 1. The electrical conductivity of the pristine FASnI₃ thin film prepared from a precursor solution without SnF₂ additives is 2.81 S cm⁻¹. This electrical conductivity is two orders of magnitude higher than the previously understood value (1.72×10⁻² S cm⁻¹) for the pristine FASnI₃ thin film prepared from a precursor solution with SnF₂ additives. It is theorized that SnF₂ additives could restrict Sn²⁺ to be oxidized to Sn⁴⁺, resulting in a stable FASnI₃ thin film, but with poor electrical conductivity. The electrical conductivity of the F4-TCNQ doped FASnI₃ thin film is dramatically enhanced to 11.03 S cm⁻¹ when the doping level of F4-TCNQ is at 1.94%. Moreover, the electrical conductivity of the F4-TCNQ doped FASnI₃ thin film with the doping level of F4-TCNQ at 3.85% is enhanced to 13.65 S cm⁻¹. Such enhanced electrical conductivity is approximately 5 times higher than that of the pristine FASnI₃ thin film prepared without SnF₂ additives and 800 times higher than that prepared with SnF₂ additives. The electrical conductivities of the F4-TCNQ doped FASnI₃ thin films when the doping levels are at 5.78% and 8.79% drop to 6.22 S cm⁻¹ and 1.12 S cm⁻¹, respectively.

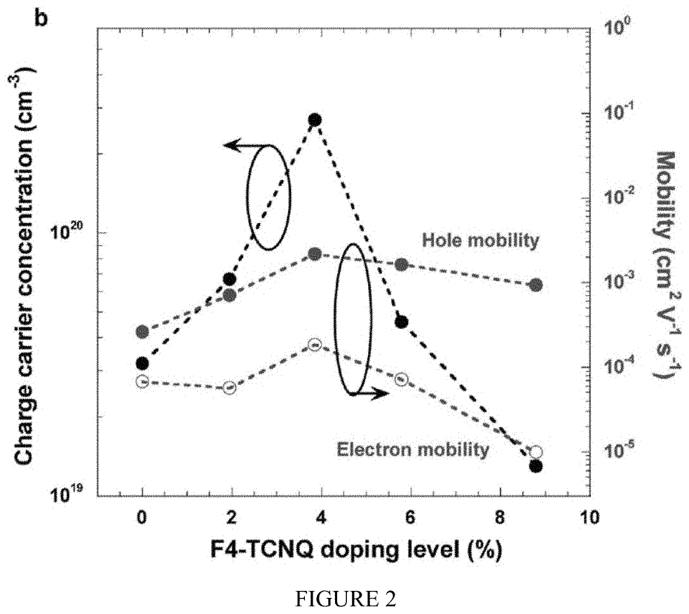

In order to understand the correlation between the electrical conductivities and the doping levels, the charge carrier concentrations (n) of the F4-TCNQ doped FASnI₃ thin films were calculated based on the capacitance-voltage measurement, according to the Mott-Schottky model. FIG. 2 presents the charge carrier concentrations of the F4-TCNQ doped FASnI₃ thin films versus the doping levels of F4-TCNQ. The charge carrier concentration of the pristine FASnI₃ thin film was calculated to be 3.2×10¹⁹ cm⁻³. A charge carrier concentration of 6.7×10¹⁹ cm⁻³ was observed from the F4-TCNQ doped FASnI₃ thin film with the doping level of F4-TCNQ at 1.94%. The charge carrier concentration is dramatically increased to 2.7×10²⁰ cm⁻³ for the F4-TCNQ doped FASnI₃ thin film when the doping level of F4-TCNQ is at 3.85%. However, as the doping levels of F4-TCNQ are increased to over 5.78%, the charge carrier concentrations of the resultant F4-TCNQ doped FASnI₃ thin films are decreased. Thus, the F4-TCNQ doped FASnI₃ thin films exhibit enhanced and then decreased electrical conductivities as doping level varies.

The charge carrier mobilities were calculated based on the space charge limited current method, according to the Mott-Gurney law. FIG. 2 also shows the charge carrier mobilities of the F4-TCNQ doped FASnI₃ thin films versus the doping levels of F4-TCNQ. The thickness of F4-TCNQ doped FASnI₃ thin films with doping levels of 0%, 1.94%, 3.85%, 5.78% and 8.79% was ˜272 nm, ˜265 nm, ˜253 nm, ˜228 nm and ˜221 nm, respectively. For the pristine FASnI₃ thin film, the electron and hole mobilities were 6.80×10⁻⁵ cm² V⁻¹ s⁻¹ and 2.63×10⁻⁴ cm² V⁻¹ s⁻¹, respectively. The electron and hole mobilities of 5.69×10⁻⁵ cm² V⁻¹ s⁻¹ and 7.08×10⁻⁴ cm² V⁻¹ s⁻¹, respectively, were observed from the F4-TCNQ doped FASnI₃ thin film when the doping level of F4-TCNQ is at 1.94%. Moreover, electron and hole mobilities of 1.85×10⁻⁴ cm² V⁻¹ s⁻¹ and 2.19×10⁻³ cm² V⁻¹ s⁻¹, respectively, were observed from the F4-TCNQ doped FASnI₃ thin film when the doping level of F4-TCNQ is at 3.85%. However, the electron and hole mobilities were decreased to 7.22×10⁻⁵ cm² V⁻¹ s⁻¹ and 1.64×10⁻³ cm² V⁻¹ s⁻¹, respectively, for the F4-TCNQ doped FASnI₃ thin film when the doping level of F4-TCNQ was at 5.78%. The electron and hole mobilities further dropped to 9.88×10⁻⁶ cm² V⁻¹ s⁻¹ and 9.33×10⁻⁴ cm² V⁻¹ s⁻¹, respectively, for the F4-TCNQ doped FASnI₃ thin film when the doping level of F4-TCNQ was at 8.79%. Thus, the F4-TCNQ doped FASnI₃ thin films exhibited enhanced and then decreased electrical conductivities as the F4-TCNQ doped FASnI₃ thin films possess increased and decreased charge carrier mobilities along with increased doping levels of F4-TCNQ.

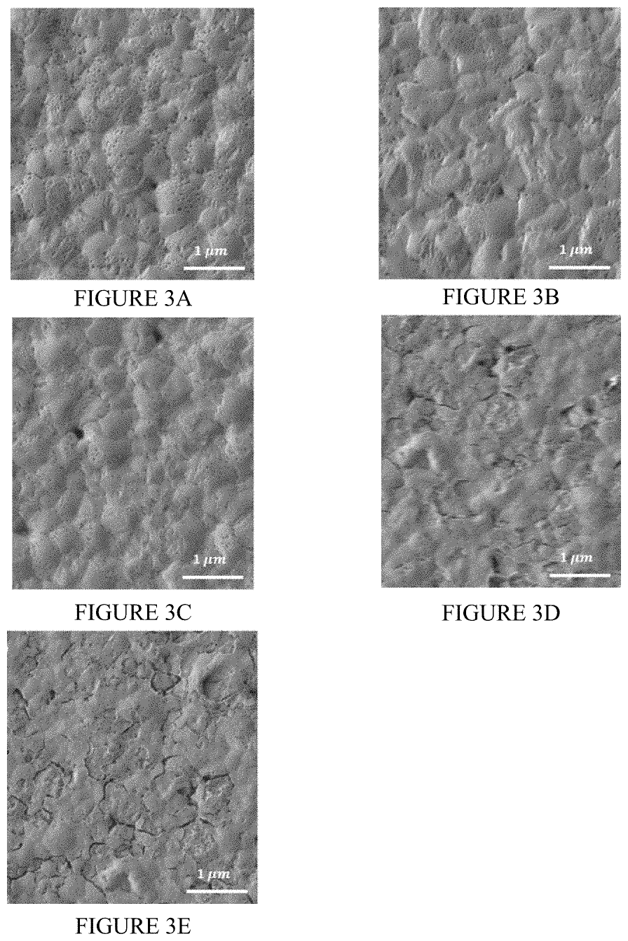

SEM was performed to study the film morphologies of the resultant F4-TCNQ doped FASnI₃ thin films to understand decreased charge carrier mobilities, and thus reduced electrical conductivities of the F4-TCNQ doped FASnI₃ thin films with high doping levels of F4-TCNQ. FIGS. 3A-3E display the top-view SEM images of the F4-TCNQ doped FASnI₃ thin films. The pristine FASnI₃ thin film possesses many pinholes, with a domain size of ˜280 nm (FIG. 3A). The pinholes are nearly diminished and the domain sizes are enlarged to ˜320 nm and ˜345 nm for the F4-TCNQ doped FASnI₃ thin films with the doping levels of F4-TCNQ at 1.94% and 3.85%, respectively (FIGS. 3B and 3C). Such superior film morphologies and enlarged domain sizes could facilitate charge carriers to be efficiently transported, resulting in enhanced charge carrier mobilities. As a result, enhanced electrical conductivities are observed from the F4-TCNQ doped FASnI₃ thin films. As indicated in FIGS. 3D and 3E, the F4-TCNQ doped FASnI₃ thin films with the doping levels of F4-TCNQ at 5.78% and 8.79% possess poor film morphologies with obvious cracks, which could restrict charge carriers to be efficiently transported, resulting in poor charge carrier mobilities. As a result, the F4-TCNQ doped FASnI₃ thin films with high doping levels of F4-TCNQ possess poor electrical conductivity.

Experimental values for the thermal conductivities of MAPbX₃ (X=Cl, Br, and I) crystals were rarely reported relative to reported theoretical values. Since micro-thermal and microthermal resistances should be considered as film thicknesses are increased to hundreds of nanometers and organic-inorganic hybrid perovskites are similar to polymers, there is a need to empirically measure thermal conductivities. The thermal conductivities of the F4-TCNQ doped FASnI₃ thin films were investigated through a quantitative thermal conductivity SThM method, which was previously used for polymers.

The thermal conductivity of the MAPbI₃ thin film was measured to be 0.5 W m⁻¹ K⁻¹. Thus, A of 2.4173×10⁴ K V⁻¹ and B of 1.1969 mA are used to calculate the thermal conductivities of the F4-TCNQ doped FASnI₃ thin films, according to the equation above. The other parameters for the F4-TCNQ doped FASnI₃ thin films are included in Table 1.

TABLE 1
Parameters for SThM model validation based on MAPbI₃ thin film.

| | K | r₀ | a | H | | | |
|---|---|---|---|---|---|---|---|
| Parameters | (W/m · k) | (nm) | (nm) | (kPa) | γ (nm) | F(nN) | m |
| Value | 0.5 | 100 | 100 | 36.49 | 11.155 | 5.97 | 0.19 |

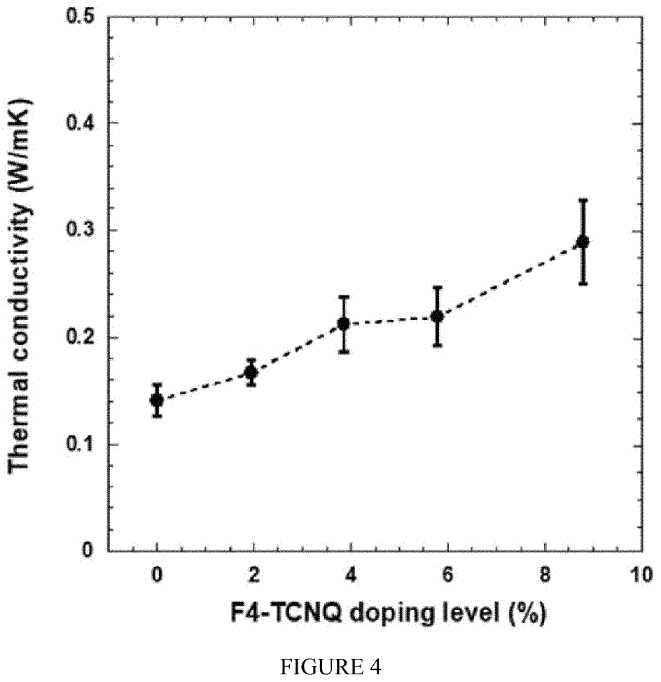

The average probe current for the pristine FASnI₃ thin film was 1.20234±0.00054 mA, whereas the average probe currents were 1.20303±0.00044 mA, 1.20469±0.00096 mA, 1.20500±0.00099 mA and 1.20778±0.00147 mA for the F4-TCNQ doped FASnI₃ thin films with the doping levels of F4-TCNQ at 1.94%, 3.85%, 5.78% and 8.79%, respectively. Thus, based on the SThM model, the thermal conductivities of the F4-TCNQ doped FASnI₃ thin films were calculated and the results are shown in FIG. 4. The thermal conductivity of the pristine FASnI₃ thin film was 0.141±0.014 W m⁻¹ K⁻¹. This is the first time the thermal conductivity of an FASnI₃ thin film has been reported. The thermal conductivities were increased to 0.167±0.012 W m⁻¹ K⁻¹, 0.212±0.026 W m⁻¹ K⁻¹, 0.219±0.027 W m⁻¹ K⁻¹ and 0.289±0.039 W m⁻¹ K⁻¹ for the F4-TCNQ doped FASnI₃ thin films with the doping levels of F4-TCNQ at 1.94%, 3.85%, 5.78% and 8.79%, respectively. As compared with those of the pristine FASnI₃ thin film, slight enhancement in the thermal conductivities of the F4-TCNQ doped FASnI₃ thin films along with increased doping levels is attributed to the electron-contribution effect. Moreover, the high thermal conductivity observed from the F4-TCNQ doped FASnI₃ thin film with the doping level of F4-TCNQ at 8.79% likely originates from large leakage probe current induced by the poor film morphology. The thermal conductivities of both the pristine FASnI₃ thin film and the F4-TCNQ doped FASnI₃ thin films were lower than those from nanostructured GeTe (˜5.5-6.3 W m⁻¹ K⁻¹), PbTe (˜2.0-3.2 W m⁻¹ K⁻¹), PbS (˜1.1-2.5 W m⁻¹ K⁻¹) and SnTe (˜3.9-8.9 W m⁻¹ K⁻¹), and even smaller than those of organic semiconductors (˜0.5 W m⁻¹ K⁻¹) at room temperature.

AFM was performed to investigate the surface roughness of thin films and to understand how the film morphology affects the probe current, and thus the thermal conductivity. The effective surface roughness of the pristine FASnI₃ thin film was estimated to be ˜69 nm, whereas the effective surface roughness of ˜59 nm, ˜47 nm, ˜57 nm and ˜77 nm were observed for the F4-TCNQ doped FASnI₃ thin films with the doping levels of F4-TCNQ at 1.94%, 3.85%, 5.78% and 8.79%, respectively. A rough surface could generate leakage current, leading to a relatively increased probe current. As a result, enhanced thermal conductivities were observed from the F4-TCNQ doped FASnI₃ thin films with the doping level at 8.79%.

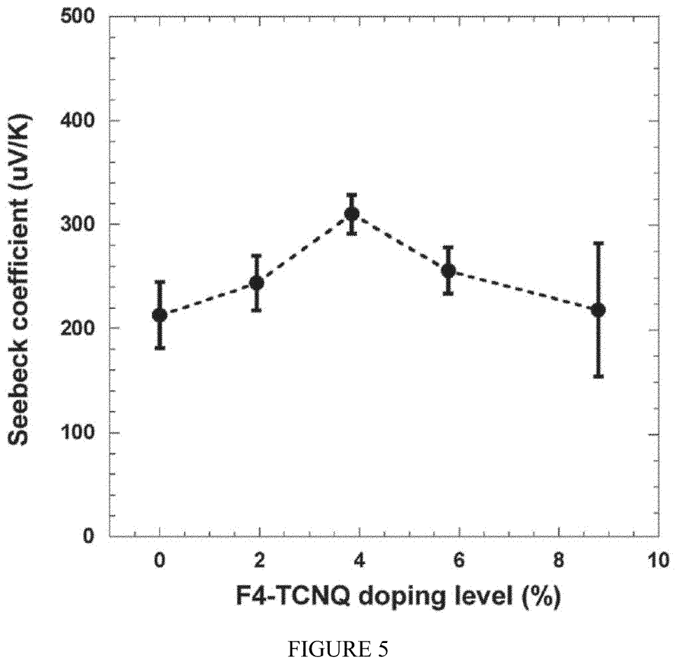

FIG. 5 presents the Seebeck coefficients of the F4-TCNQ doped FASnI₃ thin films versus the doping levels of F4-TCNQ. A positive Seebeck coefficient of ˜213 μV K⁻¹ was observed from the pristine FASnI₃ thin film. The Seebeck coefficient observed from the FASnI₃ thin film prepared in the absence of SnF₂ additives was smaller than that of the one with SnF₂ additives. This difference is attributed to the existence of Sn⁴⁺, which could induce p-type self-doping, generating a higher charge carrier concentration, consequently resulting in a smaller Seebeck coefficient. The Seebeck coefficient of the F4-TCNQ doped FASnI₃ thin film with the doping level of F4-TCNQ at 1.94% was slightly increased to ˜244 μV K⁻¹. The best Seebeck coefficient of ˜310 μV K⁻¹ was observed from the F4-TCNQ doped FASnI₃ thin film with the doping level of F4-TCNQ at 3.85%. Such enhanced Seebeck coefficients likely originate from increased narrow bands with a high density of state at the Fermi surface. The Seebeck coefficients of the FASnI₃ thin films with the doping levels of 5.78% and 8.79% drop to ˜256 μV K⁻¹ and ˜218 μV K⁻¹, respectively. These decreased Seebeck coefficients are likely due to the inferior film morphology of highly F4-TCNQ doped FASnI₃ thin films.

The pristine FASnI₃ thin film possesses a PF of 12.75 μW m⁻¹ K⁻², whereas, the F4-TCNQ doped FASnI₃ thin films with the doping levels at 1.94% and 3.85% possess PFs of 65.69 μW m⁻¹ K⁻² and 131.18 μW m⁻¹ K⁻², respectively. Such high PF values are attributed to the improved electrical conductivities and Seebeck coefficients. However, the PF value is decreased to 40.78 μW m⁻¹ K⁻² for the F4-TCNQ doped FASnI₃ thin film with the F4-TCNQ doping level at 5.78%. The PF dramatically drops to 5.34 μW m⁻¹ K⁻² for the F4-TCNQ doped FASnI₃ thin film with the F4-TCNQ doping level at 8.79%. These reduced PF values are probably attributed to the poor electrical conductivities of the F4-TCNQ doped FASnI₃ thin films.

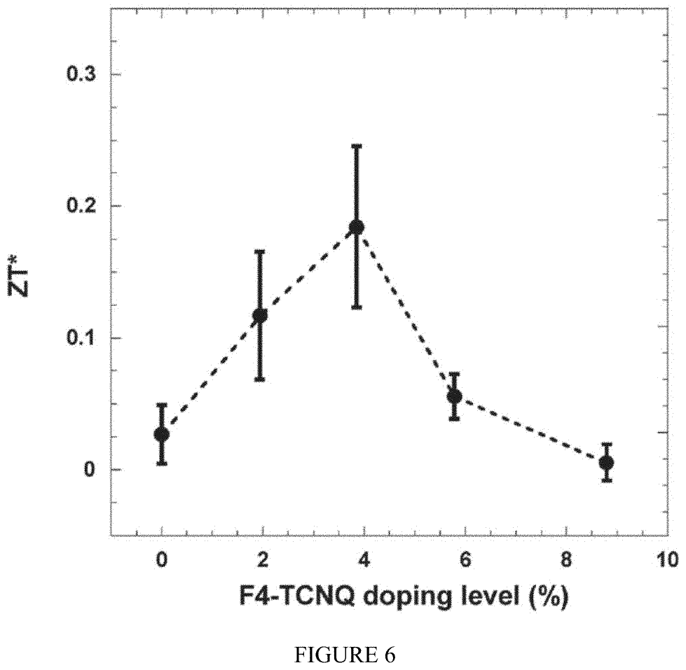

The dimensionless figure of merit, ZT, was also studied. FIG. 6 presents the ZT values of the F4-TCNQ doped FASnI₃ thin films versus the doping levels of F4-TCNQ at room temperature (T˜298 K). The pristine FASnI₃ thin film had a ZT value of 0.03. This is the first reported experimental ZT value for Sn-based perovskites. ZT values increase to 0.12 and 0.19 for the F4-TCNQ doped FASnI₃ thin films when the F4-TCNQ doping levels are at 1.94% and 3.85%, respectively. Such enhanced ZT values are ascribed to the increased electrical conductivities of the F4-TCNQ doped FASnI₃ thin films. However, ZT values are decreased to 0.06 and 0.01 for the F4-TCNQ doped FASnI₃ thin films when the F4-TCNQ doping levels are at 5.78% and 8.79%, respectively. These decreased ZT values are attributed to the poor electrical conductivities of the F4-TCNQ doped FASnI₃ thin films.

In order to enhance the thermoelectric performance of FASnI₃ thin films, F4-TCNQ was used to dope FASnI₃ thin films. Systematic studies indicated that the enhanced electrical conductivities of the F4-TCNQ doped FASnI₃ thin films are attributed to their increased charge carrier concentrations and mobilities, as well as their superior film morphologies, and decreased electrical conductivities are due to the poor film morphology of the F4-TCNQ doped FASnI₃ thin films induced by excess F4-TCNQ dopants. The thermal conductivities of the F4-TCNQ doped FASnI₃ thin films were quantitatively calculated based on the SThM method. It was found that F4-TCNQ doped Sn-based perovskite thin films exhibited ultralow thermal conductivity. Furthermore, the thermoelectric performances including the Seebeck coefficient, power factors and ZT values of the F4-TCNQ doped FASnI₃ thin films were found as described above. At room temperature, a Seebeck coefficient of ˜310 μV K⁻¹, a power factor of 130 μW m⁻¹ K⁻² and a ZT value of 0.19 were observed from the F4-TCNQ doped FASnI₃ thin films. All these results indicate that embodiments according to the present invention provide a facile and simple approach to realize enhanced thermoelectric performance from cost-effective less-toxic organic-inorganic hybrid perovskite materials.

What is claimed is:

1. A thermoelectric thin film material comprising:
a hybrid perovskite represented by the general expression
ABX₃
where A is an A-site cation, B is a B-site cation, and X is a halide anion; and
wherein the hybrid perovskite is doped with an organic dopant.

2. The thermoelectric thin film material of claim 1, wherein the A-site cation comprises one or more of CH₃NH₃¹⁺, NH₂CH₂═NH₂¹⁺, and Cs⁺.

3. The thermoelectric thin film material of claim 1, wherein the B-site cation comprises one or more of Pb²⁺ and Sn²⁺.

4. The thermoelectric thin film material of claim 3, wherein the one or more of Pb²⁺ and Sn²⁺ is partially substituted by one or more divalent metal cation selected from Cu²⁺, Ni²⁺, Fe²⁺, Mn²⁺, Pd²⁺, Cd²⁺, Ge²⁺, and Eu²⁺.

5. The thermoelectric thin film material of claim 3, wherein the one or more of Pb²⁺ and Sn²⁺ is partially substituted by one or more trivalent metal cations selected from Bi3⁺, Nd³⁺, En³⁺, and Pr³⁺.

6. The thermoelectric thin film material of claim 1, wherein the halide anion comprises one or more of Cl⁻, Br⁻, and I⁻.

7. The thermoelectric thin film material of claim 1, wherein the A-site cation is NH₂CH₂═NH₂¹⁺, wherein the B-site cation is Sn²⁺, and wherein the halide anion is I⁻.

8. The thermoelectric thin film material of claim 1, wherein the organic dopant is a p-type dopant.

9. The thermoelectric thin film material of claim 8, wherein the p-type dopant comprises at least one of TCNQ (7,7,8,8-tetracyanoquinodimethane), F4-TCNQ (2,3,5,6-tetrafluoro-7,7,8,8-tetracyanoquinodimethane), LiTFSI (Lithium bis(trifluoromethylsulphonyl)imide), FK102-Co(III)TFSi Salt (Tris(2-(1H-pyrazol-1-yl)pyridine)cobalt(III) tri[hexafluorophosphate]), Ir(mppy)₃ (Tris[2-(p-tolyl)pyridine]iridium(III)), NPNPB (N,N′-diphenyl-N,N′-di-[4-(N,N-diphenyl-amino)phenyl]benzidine), BCF (Tris(pentafluorophenyl)borane), PMA (phosphomolybdic acid), TFSA (bis(trifluoromethane)sulfonimide), MPMA (12-molybdophosphoric acid hydrate), and any derivatives thereof.

10. The thermoelectric thin film material of claim 9, wherein the p-type dopant is F4-TCNQ (2,3,5,6-tetrafluoro-7,7,8,8-tetracyanoquinodimethane).

11. The thermoelectric thin film material of claim 1, wherein the organic dopant is an n-type dopant.

12. The thermoelectric thin film material of claim 11, wherein the n-type dopant comprises at least one of o-MeO-DMBI (2-(2-methoxyphenyl)-1,3-dimethyl-2,3-dihydro-1H-benzoimidazole), PXZ-DPS (0-(4-(4-(10H-Phenoxazin-10-yl)phenylsulfonyl)phenyl)-10H-phenoxazine), BV (benzyl viologen), DQ (diquat), N-DMBI ((4-(1,3 dimethyl-2,3-dihydro-1H-benzoimidazol-2-yl)phenyl)dimethylamine), TBAI (tetrabutylammonium iodide), TBAA (tetrabutylammonium acetate), and any derivatives thereof.

13. The thermoelectric thin film material of claim 1, wherein a doping level of the hybrid perovskite is greater than about 0% based upon the molar ratio of the organic dopant and the hybrid perovskite.

14. The thermoelectric thin film material of claim 1, wherein a measured ZT value of the thermoelectric thin film is at least two times larger than a measured ZT value of an equivalent non-doped hybrid perovskite.

15. A method of making a thermoelectric thin film material, the method comprising:
forming an organic-inorganic hybrid perovskite, wherein the organic-inorganic hybrid perovskite represented by the general expression
ABX₃
where A is an A-site cation, B is a B-site cation, and X is a halide anion, and
wherein the hybrid perovskite is doped with an organic dopant.

16. The method of making a thermoelectric thin film material of claim 14, wherein the step of forming a hybrid perovskite is selected from one-step solution-processing and two-step solution-processing methods.

17. The method of making a thermoelectric thin film material of claim 16, wherein the step of forming a hybrid perovskite is a one-step solution processing method comprising:
spin coating an organic perovskite precursor, an inorganic perovskite precursor, and an organic dopant precursor, onto a substrate to thereby form a doped organic-inorganic hybrid perovskite precursor; and
converting the organic perovskite precursor, the inorganic perovskite precursor, and the organic dopant precursor, into the thermoelectric thin film material.

18. The method of making a thermoelectric thin film material of claim 16, wherein the step of forming a hybrid perovskite is a two-step solution processing method comprising:
sequentially spin coating layers of an organic perovskite precursor, an inorganic perovskite precursor, and an organic dopant precursor, onto a substrate to thereby form a doped organic-inorganic hybrid perovskite precursor; and
converting the organic perovskite precursor, the inorganic perovskite precursor, and the organic dopant precursor, into the thermoelectric thin film material.

19. A thermoelectric device comprising:
the thermoelectric thin film material according to claim 1.
